(19) United States
(12) Patent Application Publication
(10) Pub. No.: US 2024/0178789 A1
(43) Pub. Date: May 30, 2024

(54) PRISMATIC SOLAR CONCENTRATOR

(71) Applicant: KENOTOMI LTD, Kfar Chabad (IL)

(72) Inventors: Menashe ALTHOUS, Kfar Chabad (IL); Joel ERBLICH, Bnei Brak (IL)

(73) Assignee: KENOTOMI LTD, Kfar Chabad (IL)

(21) Appl. No.: 18/577,737

(22) PCT Filed: Aug. 4, 2022
(86) PCT No.: PCT/IL2022/050852

§ 371 Date: Jan. 9, 2024

Related U.S. Application Data
(63) Continuation-in-part of application No. PCT/IL2022/050852, filed on Aug. 4, 2022.
(60) Provisional application No. 63/229,796, filed on Aug. 5, 2021.

(51) Int. Cl. H02S 40/22

(52) U.S. Cl. CPC H02S 40/22

(57) ABSTRACT

A prismatic solar concentrator is provided that comprises a plurality of prisms made of transparent material, each of the prisms has a front face, and at least three back faces, wherein each of the prisms is attached to the adjacent prisms such that their front faces are aligned, forming a plate-like solar array having a flat front surface and 3-dimensional structured back surface, and a plurality of solar cells producing electrical power in response to light, wherein the plurality of solar cells is attached to some of the back faces of the plurality of prisms.

### TECHNICAL FIELD

The present subject matter relates to solar energy production devices. More specifically, the present subject matter relates to using a multi-prism solar concentrator.

### BACKGROUND

Solar energy plays an important role in variety of applications in many energy-related fields: energy for remote locations, agriculture, utility grid support, telecommunication, industrial processes, and other green environmental energy resources.

Photovoltaic (PV) cells are the leading technology to convert solar energy into electricity. Photovoltaic power systems are in wide use; however, their main drawbacks are high price and low efficiency.

Concentrators for solar cells can be used for increasing efficiency of collection but are not yet mature due to the high cost involved in building efficient collectors and sun trackers.

### BRIEF SUMMARY

According to a first aspect of the present disclosed subject matter, a prismatic solar concentrator is provided, the prismatic solar concentrator comprises: a plurality of prisms made of transparent material, each of the prisms has a front face, and at least three back faces, wherein each of the prisms is attached to the adjacent prisms such that their front faces are aligned, forming a plate-like solar array having a flat front surface and 3-dimensional structured back surface; and a plurality of solar cells producing electrical power in response to light, wherein the plurality of solar cells is attached to some of the back faces of the plurality of prisms.

In some exemplary embodiments, each of the prisms is in a form of a solid corner cube having three back faces substantially at right angle to each other.

In some exemplary embodiments, one solar cell is attached to one back face of each of the prisms, allowing light to pass through the plate-like solar array.

In some exemplary embodiments, two solar cells are attached two back faces of each of the prisms, allowing light to pass through the plate-like solar array.

In some exemplary embodiments, two solar cells are attached three back faces of each of the prisms.

In some exemplary embodiments, at least one solar cell only covers a portion of the back face it is attached to, allowing light to pass through the plate-like solar array.

In some exemplary embodiments, each of the prisms is in a form of an elongated prism having a front face, two back faces, and two ends, wherein each of the prisms is attached to an adjacent prisms at their side faces, such that their front faces are aligned, forming a plate-like solar array having a flat front surface and 3-dimensional structured back surface, wherein the plurality of solar cells is producing electrical power in response to light are attached to at least some of the back faces of the plurality of prisms.

In some exemplary embodiments, each of the prisms is a solid transparent prism.

In some exemplary embodiments, each of the prisms is a shell of transparent prism, open in the two ends.

In some exemplary embodiments, in operation, the shells of transparent prisms are filled with water.

In some exemplary embodiments, in operation, the water is flowing through the shells, cooling the solar cells.

In some exemplary embodiments, in operation, the water flowing through the shells, cooling the solar cells, heating the water, and providing hot water.

In some exemplary embodiments, at least some of the shells have holes in them to allow air circulation through the shells to cool the solar cells.

In some exemplary embodiments, the solar cells are rectangular.

In some exemplary embodiments, at least some of the solar cells is covering only a portion of the back faces they are attached to.

In some exemplary embodiments, when positioned vertically, the prismatic solar concentrator can be used as a wall or a part of a wall.

In some exemplary embodiments, when positioned vertically, the prismatic solar concentrator can be used as a fence.

In some exemplary embodiments, the fence is an acoustic fence.

In some exemplary embodiments, the three-dimensional structure of the face of the acoustic fence has better sound absorbing properties than a flat surface acoustic fence.

In some exemplary embodiments, when positioned horizontally, with its front face facing upwards, the prismatic solar concentrator can be used as a walkway.

In some exemplary embodiments, the plurality of solar cells are thin-film solar cells.

In some exemplary embodiments, the plurality of solar cells are dual-sided solar cells, intended to generate electricity in response to light received on any sided of the dual-sided solar cells.

In some exemplary embodiments, the solar cells are single-sided solar cells, intended to generate electricity in response to light received on the active face of the single-sided solar cells, and wherein the active faces of the single-sided solar cells are facing the sun-facing side of the prismatic solar concentrator, and wherein at least a portion of the light arriving to the side opposing the sun-facing side of the prismatic solar concentrator is reflected or refracted to fall on the active faces of the single-sided solar cells.

According to another aspect of the present disclosed subject matter, a flexible solar array of prisms is provided, the flexible solar array of prisms comprises: a plurality of rigid or semi-rigid elongated prisms, each having a bottom face, arranged side-by-side such that all their bottom faces are facing the same direction; a sheet of thin-film flexible solar cell attached at its first side to bottom faces of the elongated prisms, creating a flexible sheet-like solar array of prisms; and a flexible base sheet attached to the second side of the sheet of thin-film flexible solar cell.

In some exemplary embodiments, the flexible solar array of prisms can be rolled for transportation and storage, and can be unrolled to be deployed for solar energy generation.

In some exemplary embodiments, the flexible solar array of prisms is having efficiency of at least 50% larger than a corresponding area of a comparable thin-film solar cell.

Yet an aspect of the present disclosed subject matter relates to solar panel constructions. More particularly, the present disclosed subject matter relates to prisms to be used as solar panel constructions. This in contrast to solar photovoltaic panels of the art that are usually deployed as flat constructions on rooftops or other substantial horizontal surfaces that faces the radiation coming from the sun direction.

Unless otherwise defined, all technical and scientific terms used herein have the same meaning as commonly understood by one of ordinary skill in the art to which this disclosed subject matter belongs. Although methods and materials similar or equivalent to those described herein can be used in the practice or testing of the present disclosed subject matter, suitable methods and materials are described below. In case of conflict, the specification, including definitions, will control. In addition, the materials, methods, and examples are illustrative only and not intended to be limiting.

The features as indicated above can be combined individually or all together.

### BRIEF DESCRIPTION OF THE DRAWINGS

Some embodiments of the disclosed subject matter described, by way of example only, with reference to the accompanying drawings. With specific reference now to the drawings in detail, it is stressed that the particulars shown are by way of example and for purposes of illustrative discussion of the preferred embodiments of the present disclosed subject matter only, and are presented in the cause of providing what is believed to be the most useful and readily understood description of the principles and conceptual aspects of the disclosed subject matter. In this regard, no attempt is made to show structural details of the disclosed subject matter in more detail than is necessary for a fundamental understanding of the disclosed subject matter, the description taken with the drawings making apparent to those skilled in the art how the several forms of the disclosed subject matter may be embodied in practice.

In the drawings:

FIG. 1A schematically shows a single solar energy unit having a PV cell mounted on one edge of a retroreflector, in accordance with some exemplary embodiments of the disclosed subject matter.

FIG. 1B schematically shows a cross sectional view of a single hybrid solar energy unit having a PV cell mounted on one edge of a solid retroreflector, and a glass front surface, in accordance with some other exemplary embodiments of the disclosed subject matter.

FIG. 1C schematically shows a cross sectional view of a single hybrid solar energy unit augmented with a secondary PV cell for increased solar energy collection, in accordance with some other exemplary embodiments of the disclosed subject matter.

FIG. 2 schematically shows an isometric view of the back of a retroreflecting panel, in accordance with some exemplary embodiments of the disclosed subject matter.

FIG. 3A(i) schematically shows a positioning example of a hollow retroreflector mounted solar cell system, with respect to sun zenith angle, in accordance with some exemplary embodiments of the disclosed subject matter.

FIG. 3A(ii) schematically shows an example of result of ray tracing simulation of the radiation distribution on the PV cell mounted on a hollow retroreflector, in accordance with some exemplary embodiments of the disclosed subject matter.

FIG. 3B(i) schematically shows an example of PV cell mounted on a retroreflector made of refractive transparent material, in accordance with some exemplary embodiments of the disclosed subject matter.

FIG. 3B(ii) schematically shows an example of result of ray tracing simulation of the radiation distribution on the PV cell mounted on a retroreflector made of transparent material, in accordance with some exemplary embodiments of the disclosed subject matter.

FIG. 4A schematically shows an example of calculation of the generated power based on geometric ray tracing, in accordance with some exemplary embodiments of the disclosed subject matter.

FIG. 4B schematically shows the relative PV cell efficiency calculation based on the examples described in FIG. 4A, in accordance with some exemplary embodiments of the disclosed subject matter.

FIG. 5A schematically shows an isometric view of the back side of a panel made of solid transparent material, in accordance with some exemplary embodiments of the disclosed subject matter.

FIG. 5B schematically shows a back view of the side of a panel made of solid transparent material, in accordance with some exemplary embodiments of the disclosed subject matter.

FIG. 5C(i) schematically shows another view of the side of a panel made of solid transparent material, in accordance with some exemplary embodiments of the disclosed subject matter.

FIG. 5C(ii) schematically shows a cross section of a panel along the A-A line seen in FIG. 5C(i), in accordance with some exemplary embodiments of the disclosed subject matter.

FIG. 5C(iii) schematically shows a cross section of a panel along the B-B line seen in FIG. 5C(i), in accordance with some exemplary embodiments of the disclosed subject matter.

FIG. 5C(iv) schematically shows a cross section of a panel along the C-C line seen in FIG. 5C(i), in accordance with some exemplary embodiments of the disclosed subject matter.

FIG. 5C(v) schematically shows a cross section of a panel along the D-D line seen in FIG. 5C(iv), in accordance with some exemplary embodiments of the disclosed subject matter.

FIG. 6A schematically shows front view of a panel made of solid transparent material, in accordance with some exemplary embodiments of the disclosed subject matter.

FIG. 6B schematically shows a side view of a panel made of solid transparent material, in accordance with some exemplary embodiments of the disclosed subject matter.

FIG. 6C schematically shows an isometric back view of a panel made of solid transparent material, in accordance with some exemplary embodiments of the disclosed subject matter.

FIG. 7A, schematically shows an isometric view of a retroreflecting panel, in accordance with some exemplary embodiments of the disclosed subject matter.

FIG. 7B, schematically shows an isometric view of another retroreflecting panel, in accordance with some exemplary embodiments of the disclosed subject matter.

FIG. 7C, schematically shows an isometric view of another retroreflecting panel, in accordance with some exemplary embodiments of the disclosed subject matter.

FIG. 8A, schematically depicts a house with solar panel constructions installed on its roof relative to the sun trajectory according to the prior art.

FIG. 8B, schematically depicts a solar panel array constructions installed a horizontal surface, relative to the sun trajectory according to the prior art.

FIG. 9A schematically illustrates different types of surfaces to be provided with solar cells, in accordance with preferred embodiments of the disclosed subject matter.

FIG. 9B(i) schematically illustrates a cross sectional view of a solar fence, in accordance with preferred embodiments of the disclosed subject matter.

FIG. 9B(ii) schematically illustrates a cross sectional view of a solar fence having improved ballistic protection, in accordance with embodiments of the disclosed subject matter.

FIG. 9C schematically illustrates a 3-dimensional solar structure, in accordance with some exemplary embodiments of the disclosed subject matter.

FIG. 9D schematically illustrates a 3D structure that can be used in the agriculture field as roofs of greenhouse, in animal farming, or in skylight, in accordance with some exemplary embodiments of the disclosed subject matter.

FIG. 9E schematically illustrates a 3D structure, comprising a thin sheet of a material that can be transparent or not, in animal farming, or in skylight, in accordance with some exemplary embodiments of the disclosed subject matter.

FIG. 9F(i) schematically illustrates the light rays' trajectories within a solar prism, in accordance with some exemplary embodiments of the disclosed subject matter.

FIG. 9F(ii) schematically illustrates some light rays' trajectories in a vertical array of solar prisms, and the advantages of this prism, in accordance with some exemplary embodiments of the disclosed subject matter.

FIG. 9F(ii) schematically illustrates some light rays' trajectories in a vertical array of solar prisms, and the advantages of this prism, in accordance with some exemplary embodiments of the disclosed subject matter.

FIG. 9G(i) schematically illustrates a cross-sectional view of a flexible array of prisms, in its rolled state, in accordance with some exemplary embodiments of the disclosed subject matter.

FIG. 9G(ii) schematically illustrates an isometric view of a flexible array of prisms, deployed on a surface, in accordance with some exemplary embodiments of the disclosed subject matter.

FIG. 9G(iii) schematically illustrates a cross-sectional view of a flexible array of prisms, deployed on a surface, showing some path of rays, in accordance with some exemplary embodiments of the disclosed subject matter.

FIG. 10A schematically illustrates an isometric view of a semi-transparent prism, in accordance with some exemplary embodiments of the disclosed subject matter.

FIG. 10B schematically illustrates an isometric view of a semi-transparent prism, in accordance with some exemplary embodiments of the disclosed subject matter.

FIG. 11 schematically illustrates an isometric view of a solar producing glass block, in accordance with some exemplary embodiments of the disclosed subject matter.

FIG. 12 schematically illustrates a solar 3D solar panel, used as pedestrian pavement or walkway, in accordance with an embodiment of the disclosed subject matter.

### DETAILED DESCRIPTION

Before explaining at least one embodiment of the disclosed subject matter in detail, it is to be understood that the disclosed subject matter is not limited in its application to the details of construction and the arrangement of the components set forth in the following description or illustrated in the drawings. The disclosed subject matter is capable of other embodiments or of being practiced or carried out in various ways. Also, it is to be understood that the phraseology and terminology employed herein is for the purpose of description and should not be regarded as limiting. The drawings are generally not to scale. For clarity, non-essential elements were omitted from some of the drawings.

The terms “comprises”, “comprising”, “includes”, “including”, and “having” together with their conjugates mean “including but not limited to”. The term “consisting of” has the same meaning as “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this disclosed subject matter may be presented in a range format. It should be understood that the description in range format is merely for convenience and brevity and should not be construed as an inflexible limitation on the scope of the disclosed subject matter. Accordingly, the description of a range should be considered to have specifically disclosed all the possible sub-ranges as well as individual numerical values within that range.

It is appreciated that certain features of the disclosed subject matter, which are, for clarity, described in the context of separate embodiments, may also be provided in combination in a single embodiment. Conversely, various features of the disclosed subject matter, which are, for brevity, described in the context of a single embodiment, may also be provided separately or in any suitable sub-combination or as suitable in any other described embodiment of the disclosed subject matter. Certain features described in the context of various embodiments are not to be considered essential features of those embodiments, unless the embodiment is inoperative without those elements.

In discussion of the various figures described herein below, like numbers refer to like parts. Specifically, a numeral followed by a letter such as “a” or “b” may mark symmetrical elements. So as to not clutter the text, a numeral followed by the letter “x” will refer to any of the letters that follow that numeral in the drawing, for example 10x can stand for any of 10a and 10b, 10A, etc.

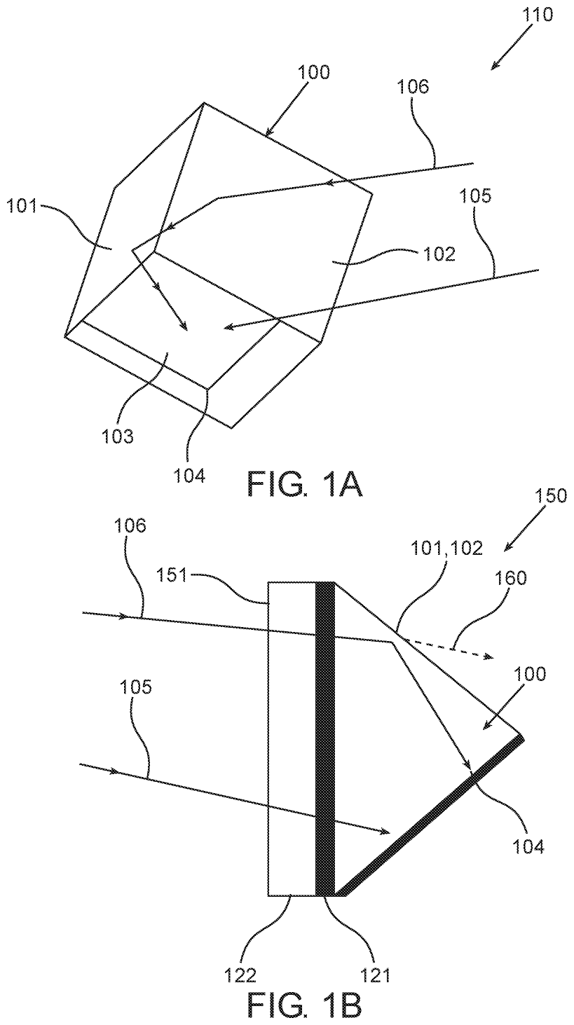

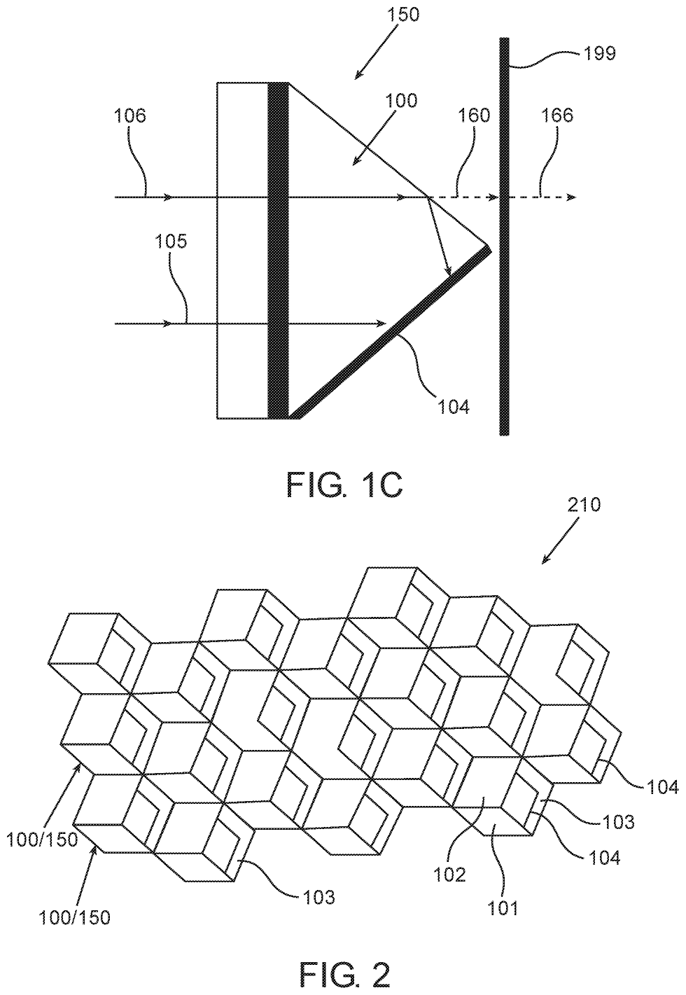

Referring now to FIG. 1A schematically showing a single solar energy unit having a PV solar cell mounted on one face of a retroreflector, in accordance with some exemplary embodiments of the disclosed subject matter.

While a single unit is seen for simplifying the drawing, a multi-unit, as would be disclosed below, can be used. The solar energy unit 110 comprises a PV solar cell 104 mounted on a retroreflector 100. Retroreflector 100 can be a hollow corner cube (shell-like), or a corner cube made of a solid transparent material.

The retroreflector 100 is in the shape of a corner cube having two reflecting surfaces 101 and 102 orthogonal to each other while the PV cell 104 is mounted on the third orthogonal surface 103. The PV cell accepts both direct radiation 105 incident on it, and reflected radiation 106 which reflects from one or both reflecting surfaces 101 or 102 of retroreflector 100.

The PV cell 104 does not necessarily covers the whole area of the retroreflector face 103. The size shape and positioning on the third orthogonal surface 103 of PV cell 104 can be optimized for example to maximize efficiency per PV cell unit area. Alternatively, the size shape and positioning on the third orthogonal surface 103 of PV cell 104 can be optimized for example to maximize the energy generated by the PV cell per unit cost of the entire energy generation unit created by placing a plurality of solar units 110.

In some embodiments, the retroreflector 100 is made of a solid cube of transparent material.

Optionally, the reflecting surfaces 101 and 102 are coated with dichroic coating to reflect the part of the spectrum relevant for generating solar power.

Optionally, the reflecting surfaces 101 and 102 can be partially transparent to allow a see-through window. For example, uncoated surfaces of a solid cube can reflect a portion of the sunlight due to the index of refraction of the transparent material which is larger than the index of refraction of air.

Referring now to FIG. 1B schematically showing a cross sectional view of a single hybrid solar energy unit having a PV solar cell mounted on one edge of a solid retroreflector, and a glass front surface, in accordance with some other exemplary embodiments of the disclosed subject matter.

While a single unit is seen for simplifying the drawing, a multi-unit, as would be disclosed below, can be used, the hybrid solar energy unit 150 is having a front glass layer 122 laminated to prismatic plastic retroreflector 100.

The front layer 122 is interconnected using optical bonding material layer 121, preferably having matching index of refraction.

The front surface 151 of front layer 122, denoted is pointing towards the sun direction can be made of thin glass such that its main purpose is to protect the hybrid solar energy unit 150 against scratch and dig. Such construction increases the durability of the hybrid solar energy unit 150 compared to hollow retroflector that collects dust in outdoors applications, or to naked plastic retroreflector which can be scratched when exposed. The vertical (or nearly vertical), scratch resisting front face collects little dust, and enables cleaning contamination that can be collected on it, thus preventing deterioration of the solar energy conversion over time.

Alternatively, front layer 122 can be made of thick high-strength glass, or a laminated glass or multilayered front layer, to create a hybrid material with improved strength, impact resistance structure. Such structure can have low weight compared with a similar glass-only layer of the same stopping capability. This panel arrangement using glass and plastic assembly can be suited for many applications due to its increased stiffness and light weight. Moreover, this prismatic arrangement concentrates sun radiation form relatively large input aperture to a relatively small solar cell.

Additionally, some of the reflected radiation 106 need not be completely reflected by the reflecting surfaces 101 or 102, and the penetrated radiation 160 provide some light to the interior of the structure if solar energy units 110 or hybrid solar energy units 150 are installed as a window or a ceiling of a building.

Referring now to FIG. 1C schematically showing a cross sectional view of a single hybrid solar energy unit 150 augmented with a secondary PV solar cell 199 for increased solar energy collection, in accordance with some other exemplary embodiments of the disclosed subject matter.

Penetrated radiation 160 can be captured by installing a secondary PV solar cell 199 behind hybrid solar energy unit 150 (with or without optional front layer 122).

Using a semi-transparent secondary PV cell 199 allows some residual radiation 166 to penetrate through and to provide some lighting to the interior of the building.

Referring now to FIG. 2, schematically showing an isometric view of the back a retroreflecting panel, in accordance with some exemplary embodiments of the disclosed subject matter.

The side of a panel, or a solar energy unit which is facing the sun is referred to as the “front”, while the side which is away from the sun is referred to as the “back”.

The figure shows an example of panel 210 intended to generate solar energy, comprising a two-dimensional array of solar energy units 110 or hybrid solar energy unit 150.

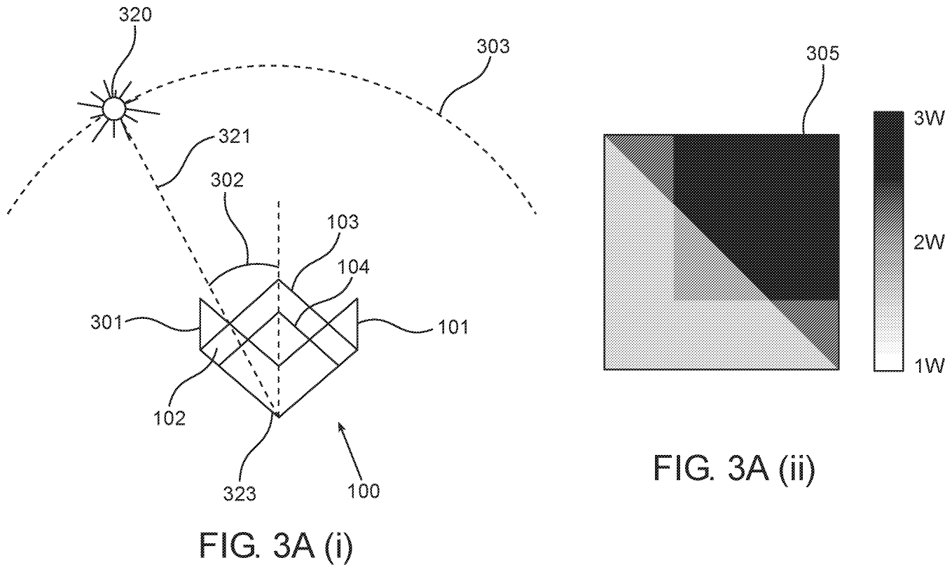

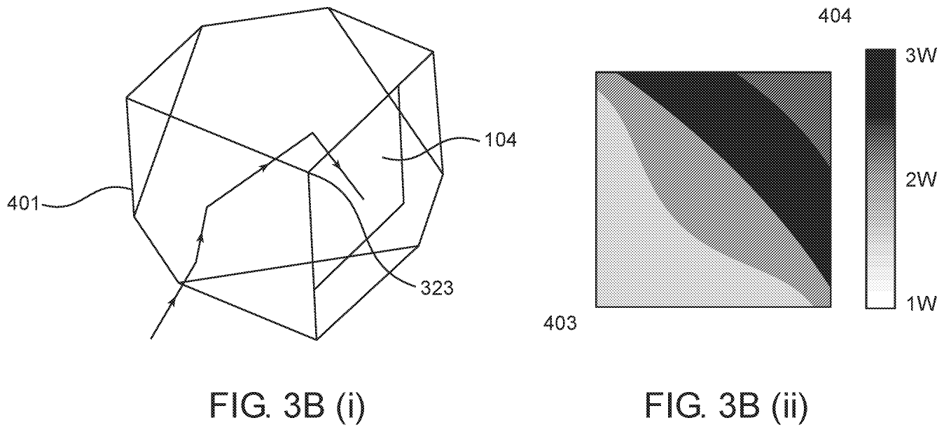

Referring now to FIG. 3A(i) schematically showing a positioning example of a hollow retroreflector mounted solar cell system, with respect to sun zenith angle, in accordance with some exemplary embodiments of the disclosed subject matter.

FIG. 3A(i) shows the positioning of a hollow retroreflector mounted solar cell system 301, with respect to sun zenith angle 302 and path 303 of the sun 320 in the sky.

It should be noted the path 303 of the sun 320 in the sky depends on the latitude and the date, while the location of the sun along the path 303 depends on the time of the day. In places near the equator, path 303 climes higher and in northern or southern countries, the path stays closer to the horizon even in mid-day. Thus, the vector 321 from the sun 320 to the vortex 323 of the retroreflector 100 (or 150) depends on the latitude, the date in the year and the time in the day.

Orientation of the retroreflector 100 (or 150) affects the solar energy collection as a function of the latitude, the date in the year and the time in the day. For a specific application, and knowing the latitude where the system is to be installed, the orientation of the retroreflector 100 can be selected to meet the needs. For example, the orientation can be selected to provide best overall yearly average efficiency. Alternatively, the orientation can be selected to provide better efficiency at the time of the year when more power is needed. Alternatively, the orientation can be selected to provide better efficiency at the time of the day when more power is needed. Yet alternatively, the orientation can be selected to provide more even distribution of the efficiency throughout the year or the time of the day

Referring now to FIG. 3A(ii) schematically showing an example of result of ray tracing simulation of the radiation distribution on the PV solar cell mounted on a hollow retroreflector, in accordance with some exemplary embodiments of the disclosed subject matter.

The image 304 shows an example of ray tracing simulation of the radiation distribution on the PV cell area. The color scale shows several areas receiving radiation with intensity ranging from W (direct sun radiation) to 3W due to addition of radiation reflected from two other retroreflector surfaces. The point 305 denotes the PV cell corner coinciding with the retroreflector vertex. It should be noticed that the PV cell still gains from other surfaces reflections even beyond the regular acceptance angle for back reflection of the incident light beam.

Referring now to FIG. 3B(i) schematically showing an example of PV solar cell mounted on a retroreflector made of refractive transparent material, in accordance with some exemplary embodiments of the disclosed subject matter.

Schematic layout of retroreflector made of refractive transparent material 401 with PV solar cell 104 mounted on one edge. The retroreflector is made of a refractive transparent material with three orthogonal edges reflecting the incident radiation by total internal reflection and/or additional reflecting coating. The PV cell 104 is mounted on the retroreflector surface by means of a refraction index matching material to optimize the radiation coupling.

Referring now to FIG. 3A(ii) schematically showing an example of result of ray tracing simulation of the radiation distribution on the PV solar cell mounted on a retroreflector made of transparent material, in accordance with some exemplary embodiments of the disclosed subject matter.

The image 403 shows an example of ray tracing simulation of the radiation distribution on the PV cell area. The point 404 denotes the PV cell corner coinciding with the retroreflector vertex 323.

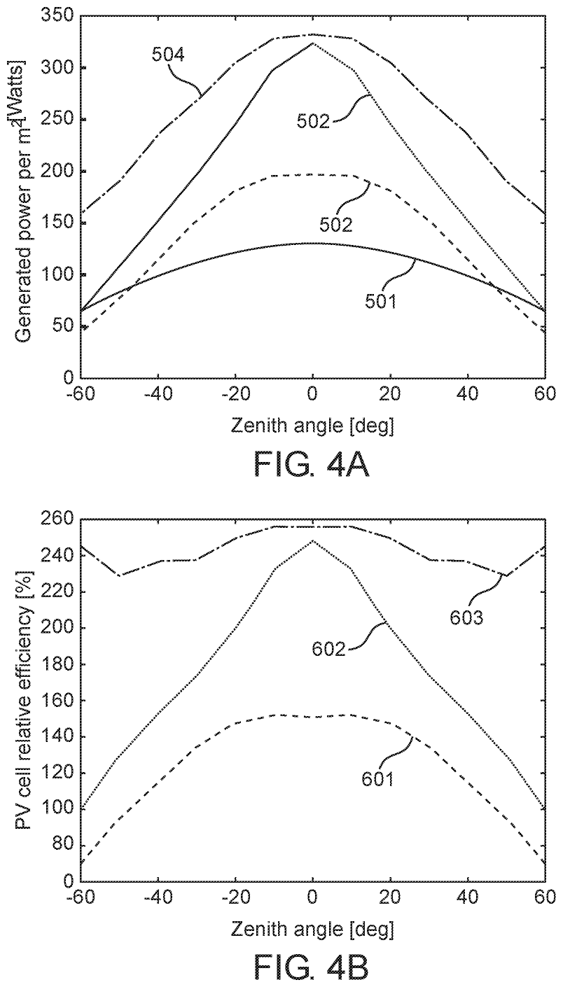

Referring now to FIG. 4A schematically showing an example of calculation of the generated power based on geometric ray tracing, in accordance with some exemplary embodiments of the disclosed subject matter.

Example calculation of the generated power based on geometric ray tracing is shown in FIG. 4A. The PV solar cell is assumed to have 13% efficiency and incident radiation is 1000 W per square cm were assumed. The plot shows the power generated by 1 square meter of PV cells on a prior art flat panel and different examples of retroreflectors versus the sun zenith angle 302 from −60 to +60 degrees. Line 501 shows the generated power by prior art flat PV panel of 1 square meter area for comparison.

Line 502 shows the power generated by a panel such as seen in FIG. 2A, comprising 100 hollow retroreflector units with 175 cm cross sectional area with 100 cm\hat{ }2 PV solar cell each (covering the whole retroreflector edge).

Line 503 shows the power generated by the same 200 hollow retroreflector units with 50 cm\hat{ }2 PV cell (covering half of the retroreflector face area) positioned at the retroreflector vertex.

Line 504 shows the power generated by 200 refractive retroreflectors made of transparent material, such as seen in FIG. 3B (described in FIG. 4) with 175 cm\hat{ }2 cross section area and 50 cm\hat{ }2 PV cell positioned at the retroreflector vertex.

Referring now to FIG. 4B schematically showing the relative PV solar cell efficiency calculation based on the examples described in FIG. 4A, in accordance with some exemplary embodiments of the disclosed subject matter.

The figure shows the relative PV solar cell efficiency calculation based on the examples described in FIG. 4A. The plot shows the PV cell solar power generation efficiency based on the present subject matter with respect to prior art PV cells mounted on flat panels.

The efficiency is calculated for equal area of PV cells of 1 square meter mounted on retroreflectors, with respect to PV cells mounted on prior art flat panel.

Curve 601 represents the efficiency of 100 hollow retroreflector units with 100 square cm PV cell.

Curve 602 represents the efficiency of 200 hollow retroreflector units with 50 cm\hat{ }2 PV cell mounted close to the retroreflector vertex.

Curve 603 represents the efficiency of 200 refractive retroreflectors made of transparent material with 50 cm\hat{ }2 PV cell mounted close to vertex. Should be noticed that the refractive retroreflectors array has almost constant efficiency for solar zenith angles 302 from −60° to +60°. This clearly shows that the present subject matter enables up to 250% more solar energy to be generated by standard solar cells.

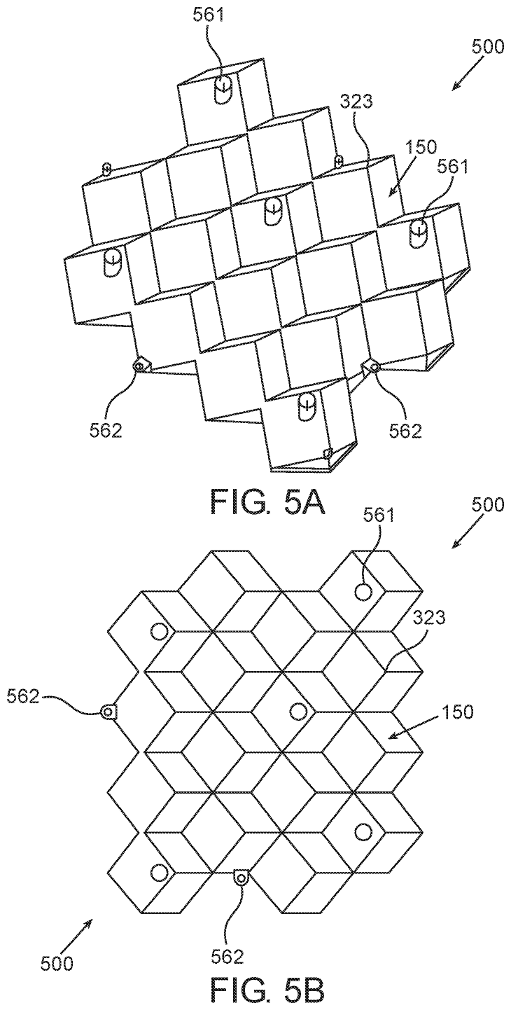

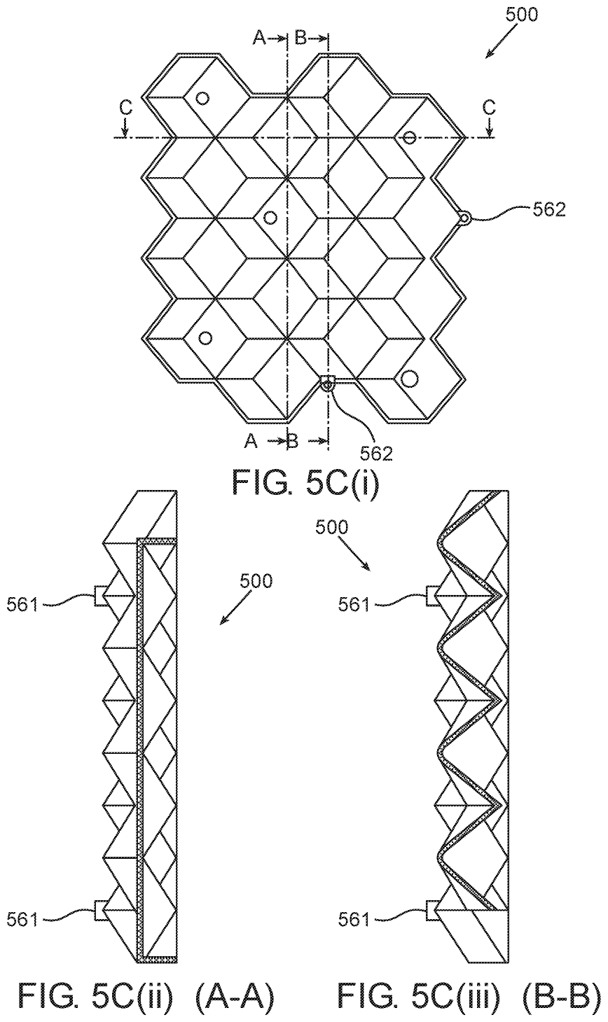

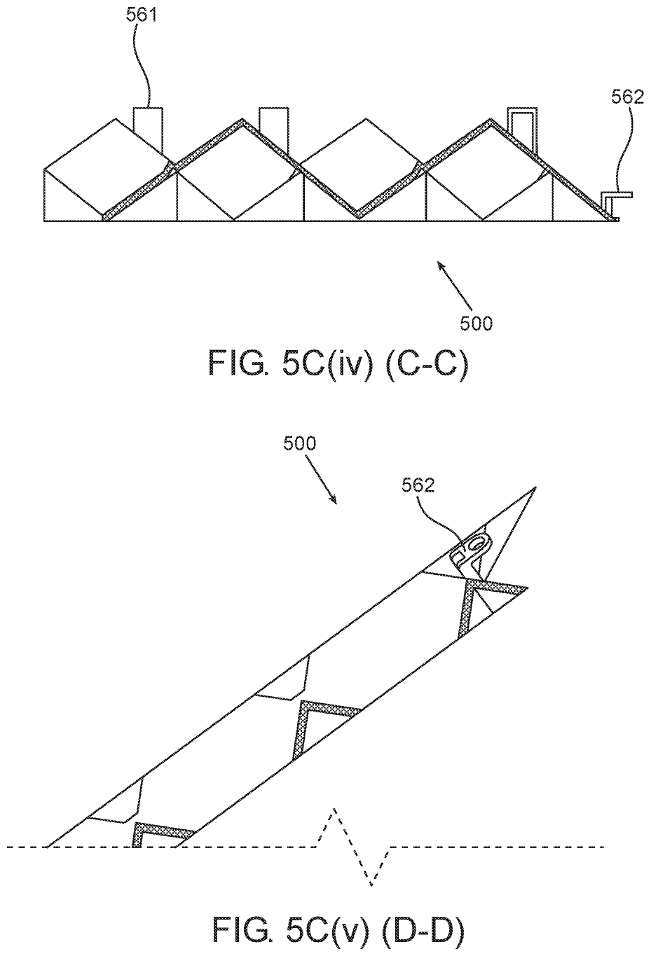

FIGS. 5A to 5C(v) show detailed engineering drawings of a plate-like panel 500 made of solid transparent material having an array of four-by-four retroreflectors 150 prior to the installation of the PV solar cells, and prior to the optional installation of front glass layer 122. Dimensions are in mm. It should be noted that these drawings are to be viewed as a non-limiting example, and different array size and shape, as well as other dimensions can be selected.

Referring now to FIG. 5A schematically showing an isometric view of the back side of a panel made of solid transparent material, in accordance with some exemplary embodiments of the disclosed subject matter.

FIG. 5A shows the back of a panel 500 comprises an array of 4×4 retroflectors 150 prior to the installation of the PV solar cells.

Panel 500 is manufactured for example using injection molding or other mass production methods. Panel 500 is constructed such that a plurality of such panels can be placed side-by-side to cover a large area without substantial gaps. It should be noted that a single, large front glass layer 122 can be used with a plurality of side-by-side front glass layer 122 to create a large area solar collecting unit.

Mounting pols 561 used for mounting the panel to a frame.

Referring now to FIG. 5B schematically showing a back view of the side of a panel made of solid transparent material, in accordance with some exemplary embodiments of the disclosed subject matter.

Referring now to FIG. 5C(i) schematically showing another view of the side of a panel made of solid transparent material 500, in accordance with some exemplary embodiments of the disclosed subject matter.

Lines marked A-A, B-B, and C-C mark the locations of cross sections seen in FIGS. 5c(ii), 5C(iii) and 5C(iv) respectively.

Referring now to FIG. 5C(ii) schematically showing a cross section of panel 500 along the A-A line seen in FIG. 5C(i), in accordance with some exemplary embodiments of the disclosed subject matter.

Referring now to FIG. 5C(iii) schematically showing a cross section of panel 500 along the B-B line seen in FIG. 5C(i), in accordance with some exemplary embodiments of the disclosed subject matter.

Referring now to FIG. 5C(iv) schematically showing a cross section of panel 500 along the C-C line seen in FIG. 5C(i), in accordance with some exemplary embodiments of the disclosed subject matter.

Line marked D-D marks the location of cross section seen in FIG. 5C(v).

Referring now to FIG. 5C(v) schematically showing a cross section of panel 500 along the D-D line seen in FIG. 5C(iv), in accordance with some exemplary embodiments of the disclosed subject matter.

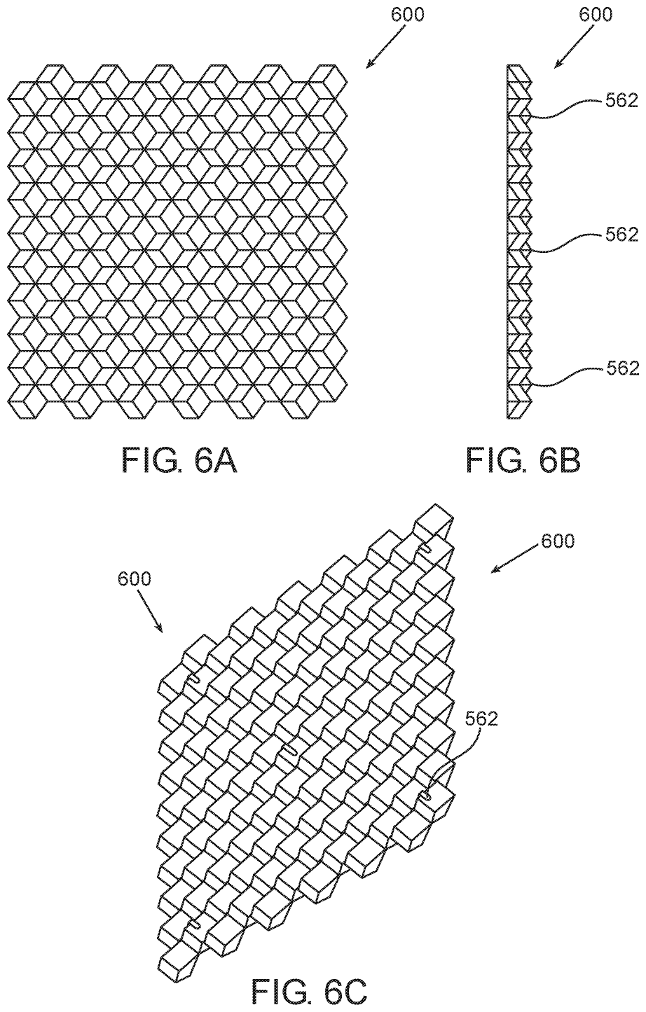

FIGS. 6A to 6C show drawings of a plate-like panel 600 made of solid transparent material having an array of 10 by 12 retroreflectors 150 prior to the installation of the PV solar cells, and prior to the optional installation of front glass layer 122. Dimensions are in mm. It should be noted that these drawings are to be viewed as a non-limiting example, and different array size and shape, as well as other dimensions can be selected.

Referring now to FIG. 6A schematically showing front view of a panel 600 made of solid transparent material, in accordance with some exemplary embodiments of the disclosed subject matter.

Referring now to FIG. 6B schematically showing side view of a panel 600 made of solid transparent material, in accordance with some exemplary embodiments of the disclosed subject matter.

Mounting posts 562 can be seen in this view.

Referring now to FIG. 6C schematically showing an isometric back view of a panel 600 made of solid transparent material, in accordance with some exemplary embodiments of the disclosed subject matter.

Mounting posts 562 can be seen in this view.

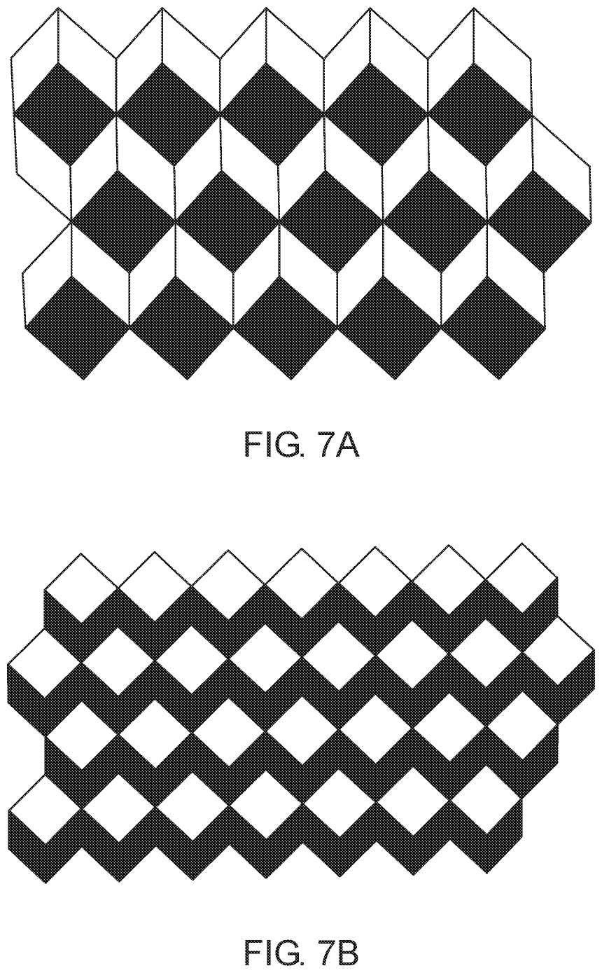

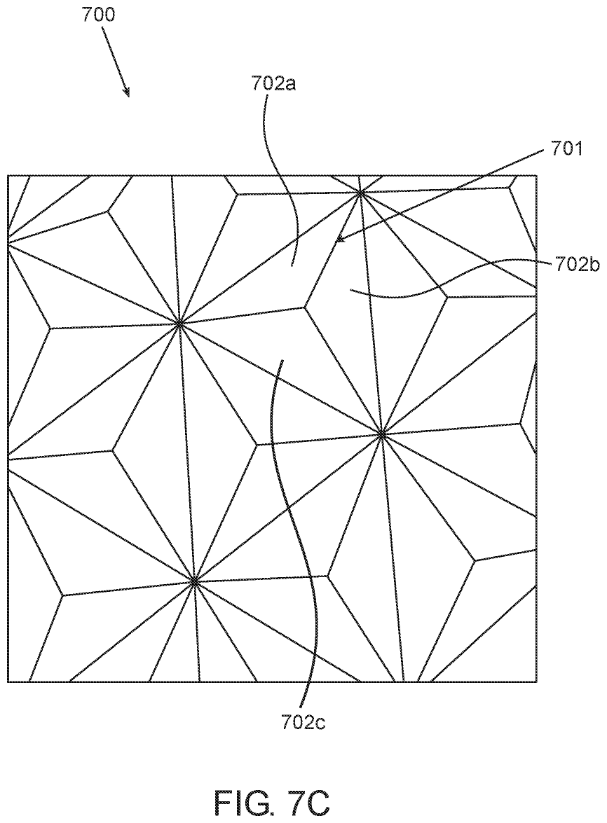

Referring now to FIG. 7A schematically showing an isometric view of a retroreflecting plate-like panel, in accordance with some exemplary embodiments of the disclosed subject matter.

The solar energy multi-unit is shown to comprise a single PV solar cell mounted on the back side of each corresponding retroreflector. The Retroreflector can be a hollow corner cube (shell-like), or a corner cube made of a solid transparent material. The retroreflector is similar to retroreflector 100 in FIG. 2 however, the PV cell is on the whole side of the cube on not on a part of it.

Referring now to FIG. 7B schematically showing two PV solar cells adhered on both sides of the corresponding retroreflector cube, in accordance with some exemplary embodiments of the disclosed subject matter.

The plate-like structure seen in FIGS. 7A and 7B can be used for skylights or billboards. These structures can use the sun light while it moves from one side of the structure to the other.

These types of panels can be enclosed within glasses from both sides and framed so it will be impermeable.

In some embodiment, the retroreflectors disclosed above are made of polycarbonate. However, other plastic materials having similar characteristics be used as well without limiting the scope of the present subject matter. Alternatively, glass can be used. Polycarbonate is preferred due to its strength and/or weight, and/or cost.

The retroreflectors disclosed above can act to protect the PV solar cells from adverse weather, increasing reliability and longevity of the system. Additionally, the panel can provide thermal isolation and heat dissipation, increasing the efficiency of the PV cells.

The panels disclosed above, when used in a building, as a window, ceiling, or wall covers, provide thermal isolation to the building, reducing energy consumption for heating and/or cooling.

For example, the semi-transparent panels disclosed above can be used in walls and/or celling of a green house, providing power and allowing enough sunlight to penetrate and promote plant growth. Similarly, the semi-transparent panels disclosed above can be used in celling of shades. For example, garden shades or gazebos, or farm animals shelter structures.

The panels disclosed above, can be used as floors in terraces, bicycle lanes, and sidewalks and in other places where sunlight impinges the floor. In these applications, using a glass cover layer is preferable.

Optionally, sensors can be integrated into the panels disclosed above. For example, such sensors can monitor environmental parameters such as temperature, humidity, etc. The sensor can be used to control the use of the produced electrical energy, for example activating house air conditioning and the likes. In a roadside application, the sensors can monitor traffic condition, control traffic lights and alert signs, and be used in “smart highway” applications.

The panels disclosed above can be used at the back of street signs or advertisement signs or billboards, for providing power to the grid, or for illuminating the sign using an energy storage device such as rechargeable battery. The panel can be used also as the backing and frame for the sign, reducing installation costs.

Similarly, in urban environment, the sensors can monitor traffic condition, pedestrian activity, the panels can power and control traffic lights, surveillance cameras and alert signs, and be used in “smart city” applications.

Flexible PV solar cells can be glued to the solar energy unit (100, 150), or used for the secondary PV cell (198, 199).

The panels disclosed above, can save installation cost due to their higher rigidity compared to conventional PV cell that requires backing and frame to be installed.

In some jurisdictions, installing PV cells is constrained by the requirement that reflected sunlight would not blind nearby people. Thus, vertically mounting a conventional PV cell cannot be allowed below a threshold height above ground. Due to the low light reflection of the panels disclosed above, these restrictions can overcome.

Referring now to FIG. 7C, schematically showing an isometric view of another plate-like retroreflecting panel, in accordance with some exemplary embodiments of the disclosed subject matter.

In this figure, a solar concentrator 700, having a plurality of tetrahedral prisms 701 is seen. In some embodiments, solar cells are attached to one, two, or all three of the outer triangular surfaces 702a, 702b or 702c. In some embodiments the solar cells are attached to the outside surfaces (facing the viewer in this figure) of the outer triangular surfaces 702a, 702b or 702c. Alternatively, solar cells are attached to all or some of the bases of the tetrahedral prisms 701 (not seen in this isometric view). This embodiment is useful when the tetrahedral prisms 701 are solid structures made of clear material. Optionally, a protective layer is covering the solar cells. The attached solar cells can cover the corresponding surface, or cover some portion of it.

In other embodiments, the solar concentrator 700 is having a plurality of empty tetrahedral prisms such that the structure is a corrugated clear surface. In these embodiments, the solar cells can also be attached to on the inside surfaces of triangular back faces 702a, 702b or 702c (facing away from viewer in this figure).

It should be noted that the triangular back faces 702a, 702b or 702c that appear to be equal in this figure are to be considered as a demonstration only, and the they can be of different shape, to be optimized for the relative angle of the sun, depending on the latitude of installation, the orientation of installation (vertical, horizontal or oblique), and other parameters such as the time of day in which peak energy production efficiency is preferred, typical weather conditions such a clouds and fog, etc. Same adaptations can be used for other prism shapes disclosed in herein.

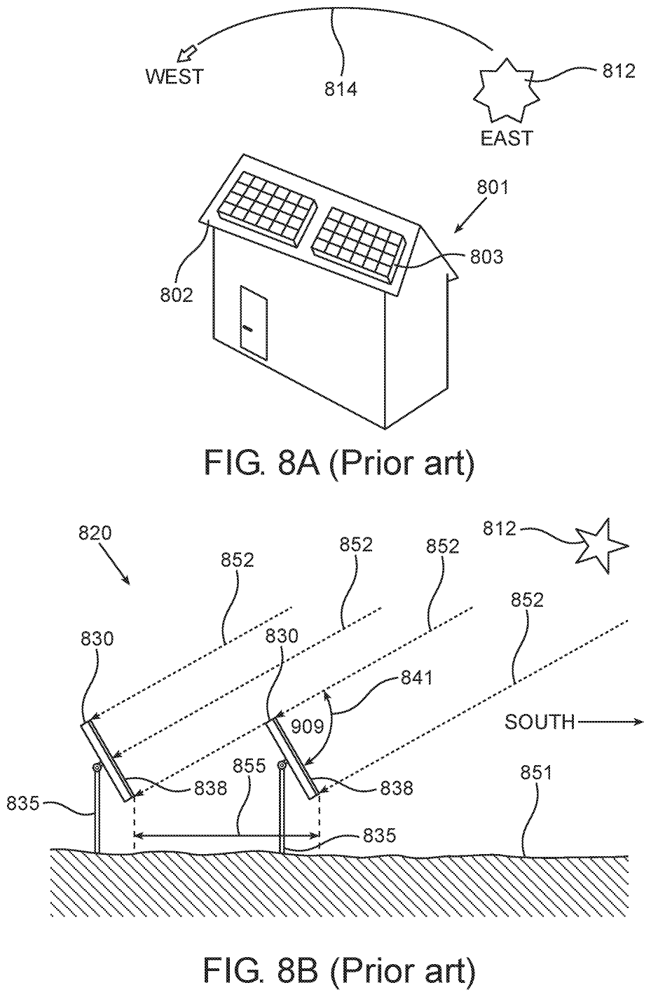

Reference is now made to FIG. 8A, schematically depicting a house with solar panel constructions installed on its roof relative to the sun trajectory, according to the prior art.

A house, or other structure such as house 801 is illustrated to have a slanted roof 802 onto which a construction is built with solar panels 803. The construction itself is heavy while its installation is cumbersome. The sun 812 is travelling during the day in a trajectory 814 from the east to the west and the solar panel has to be installed on the roof preferably in an angle that is directed to the south, so as to effectively maximize the time of light radiation. This markedly limits the roofs' areas onto which the solar panels can be installed in order to work effectively. In some cases, in order to get the correct angle towards the south, a metal construction is built to support the main construction with the solar cells. This adds to the cost of the energy generation system.

Another limitation of prior art solar panels is that the solar cells are encapsulated within an opaque construction. If the roof has skylight, this limits the area onto which the panels can be installed since it nulls the skylight or any other openings on the roof. Moreover, there are roofs that needs to be able to allow sunlight to pass through them and such a construction as shown in FIG. 1 cannot be used in such cases since they block the sun light.

As not all houses are built with optimally slanted or oriented roof, the efficiency of the energy collection can be compromised. It should be noted that the efficiency of the energy collection is compromised while the sun is changing its location in the sky during the day (in any location) and during the year (away from the equator).

Reference is now made to FIG. 8B, schematically depicting a solar panel array constructions installed on a horizontal surface, relative to the sun trajectory, according to the prior art.

Solar array 820 comprises a plurality of flat solar panels 838 (seen here from the side), each installed on a support surface 830, that is installed on a corresponding support structure 835. In order to optimize the energy generation, the panels are oriented such that the angle 841 between the sun rays 852 and the surface of the solar panels 838 is close to 90 degrees when the sun 812 is at its highest position. To avoid shadowing of one panel by the adjacent one, the distance 855 between adjacent panels needs to be maintained. This causes gaps between adjacent panels, and incomplete coverage of the surface 851 on which the array 820 is positioned. As the sun moves in its daily and seasonally trajectories, shadowing and/or unused gaps between panels are unavoidable.

Seasonal adjustment of the tilt of panels 838 requires periodic adjustment (tilting) the orientation of the support surface 830 in respect to the structure 835. This adds complexly and cost to the solar system as well as increases the maintenance cost.

Since the support surface 830 is opaque, sunlight, direct or scattered cannot pass through it to illuminate the solar panels 838 from behind.

It should be noted that “dual-sided” solar cells, designed to produce electricity if illuminated on other sides, are available. However, these are costly. Solar panels designed for one-sided illumination do generates electricity (at lower efficiency) when illuminated from their back side. However, in a conventional solar panel (seen for example in this figure), having opaque support surface, back illumination is impossible.

It is an object of the present subject matter to provide a solar construction comprising three-dimensional shapes that overcome at least some of the shortcoming of prior art solar arrays seen in FIGS. 8A and 8B.

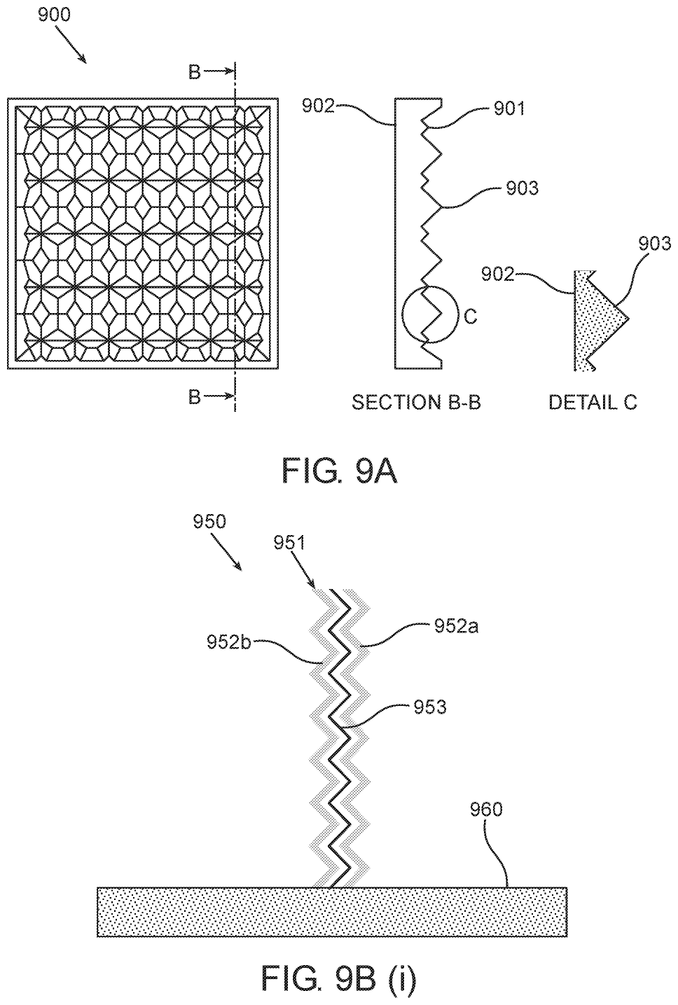

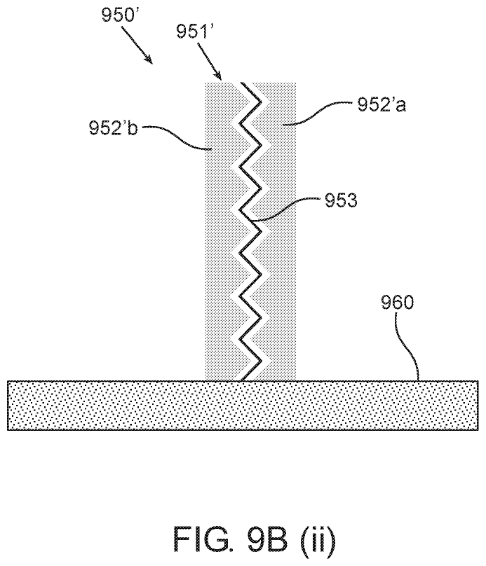

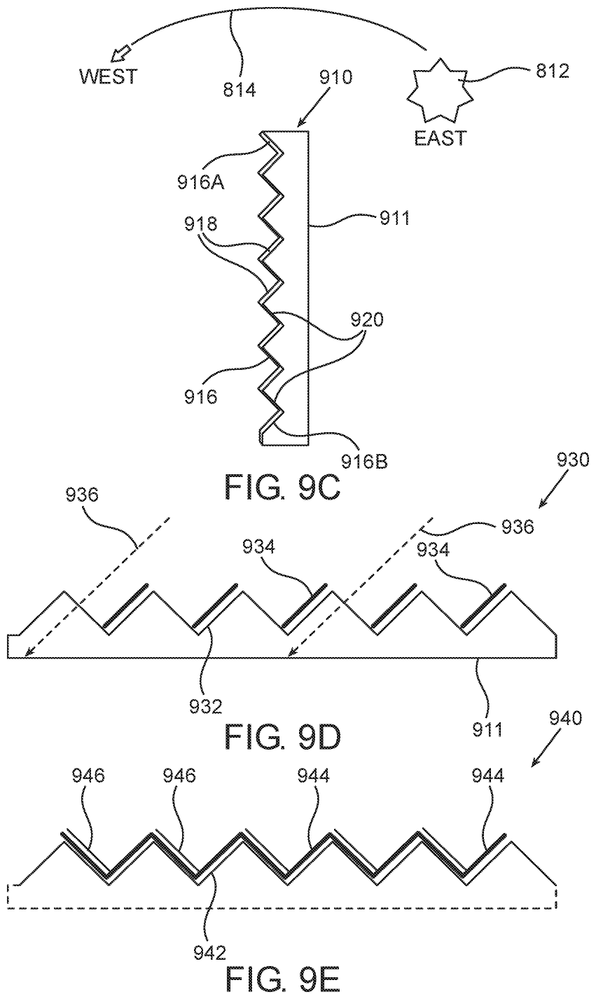

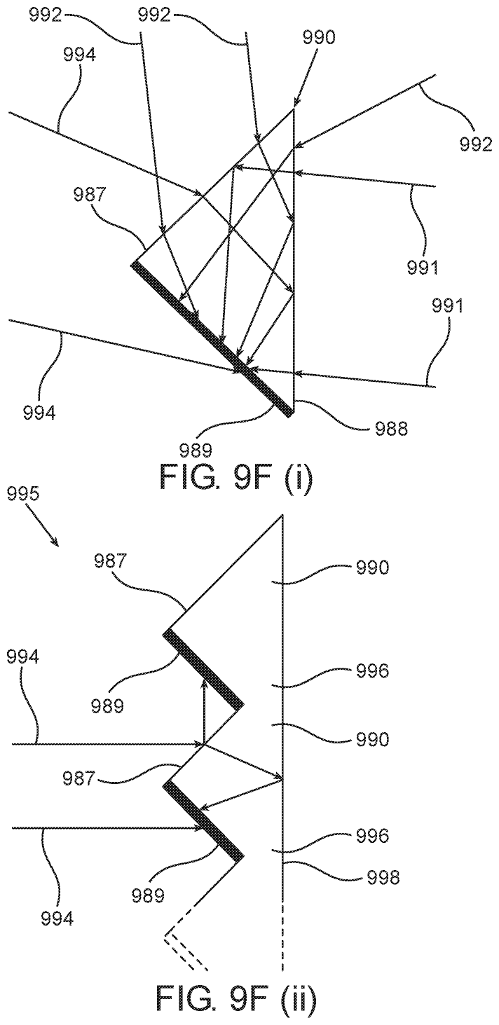

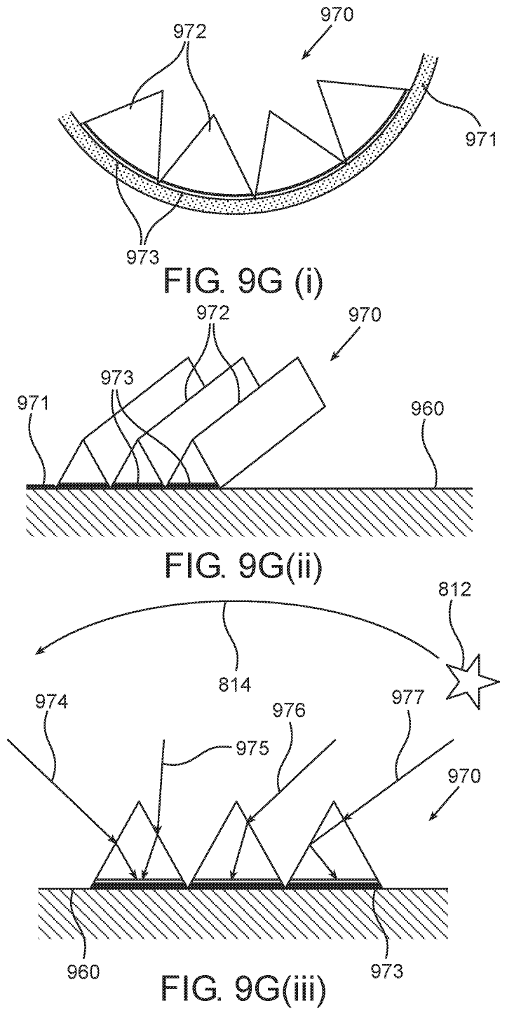

Referring now to FIG. 9A schematically illustrating a plate having a plurality of 3D prisms to be provided with solar cells, in accordance with preferred embodiments of the disclosed subject matter.

Different types of plates having 3D structure having sides that are oriented in many directions can be used, while the solar cells can be provided on some of the sides, using the transfer of light within the structure.

The structure 900 can be a bulk plate having a flat face 902 and a patterned back face 903 as seen in the cross-sections, or a thin shell 901 onto which the solar cells are adhered or embedded within. The face of the structure can be seen as well as a cross sectional views (B), and the enlargement (C), showing the many sides of the structure and their depth.

Vertically oriented structures containing prismatic structures such as disclosed in this document can be used as solar fences that combines solar energy generation with a physical barrier.

The geometric shapes increase the area of the solar cells up to three times the area of the structure 900, and thus a solar generating unit based on this structure gives higher light utilization than a standard panel of comparable size because it has both more space of solar cells and double-sided operation.

Referring now to FIG. 9B(i) schematically illustrating a cross sectional view of a solar fence, in accordance with embodiments of the disclosed subject matter.

The solar fence 950 is seen in this example, is anchored vertically to the ground 960. In the cross-sectional view of solar fence 950, it can be seen how the solar panel 951 is made of two transparent plastic or glass panels 952a and 952b in a three-dimensional zig-zag shape, while between the two panels 952a and 952b, there is provided double-sided solar cells sheet 953 that receives light from both sides of the fence and thus, more hours of sun exposure are possible. In some embodiments, single-sided solar cells are used. In some embodiments one of the panels, which faces away from the sun is made of opaque material, for example metal.

The fence will receive more hours of sunshine than a regular panel because it receives sun light all day even when the sun is in the east, when the sun is in the south, and also when the sun is in the west.

The solar fence provides good solution for places where it is not appropriate to put ordinary solar panels, such as roadsides, sides of railway tracks, charging points for electric vehicles, agricultural fields and any place where there is not enough space to put ordinary panels.

The solar fence can be partially transparent, or have parts that are transparent or semitransparent, or a combination thereof. The solar fences can be installed within agricultural areas, as a separation fences in roads, walls, acoustic walls, near electrical public transportation, in the vicinity of electrical vehicles charging, spots facilities, and the likes, to provide physical structural benefits as well as providing solar power.

It should be noted that the solar cells are embedded between the two-sided fence or a one-sided fence. The two-sided fence takes advantage of the sun light in any orientation.

The transparent materials used in the solar fences can be polycarbonate, PVC, acryl, glass, a combination thereof, and the likes. These structures that are vertical provides more exposed surfaces in a relatively small area on the ground.

It should be noted that the energy production of the solar cells can be performed in corrugated and differently oriented surfaces. Another advantage of the solar fences is their lack, or reduction of sunlight and car headlight reflection towards the people that are using the roads.

Additional advantage of the structured face of the solar fence seen herein is its sound absorption properties. Unlike a flat surface that mainly reflects sound, structured surface disperses and absorbs soundwaves.

Referring now to FIG. 9B(ii) schematically illustrating a cross sectional view of a solar fence providing improved ballistic protection, in accordance with other embodiments of the disclosed subject matter.

The solar fence 950′ is seen in this example, anchored vertically to the ground 960. In the cross-sectional view of solar fence 950′, it can be seen how the panel 951′ is made of two transparent plastic or glass panels 952′a and 952b′ in a three-dimensional shape while between the two panels 952′a and 952′b, there is provided double-sided solar cells sheet 953 that receives light from both sides of the fence, and thus, more hours of sun exposure are possible. However, a single-sided solar cells sheet can be used, specifically, when the fence 950′ is install along the east-west direction, such that sunlight is falling mainly on one of its sides. Additionally, some single-sided solar cells do generate electricity (at reduced efficiency) when illuminated on their back side. Generally, single-sided solar cells are cheaper than double-sided solar cells.

It should be noted that some of the prisms disclosed in this document provide two-sided operation of the energy collecting unit without the use of the more expensive double-sided solar cells. Moreover, experiments show that the use of double-sided solar cells adds only 10% to 20% increased efficiency, while the use of prisms can add up to 60% added efficiency. This is specifically important in countries where the sun is low in the sky.

All attributes and advantages of solar fence 950 and solar fence 950′ are same or similar.

However, panels 952′a and 952′b, are thicker, and preferably, when combined to form the solar fence providing improved ballistic protection 950′, they interlock to form a thick fence having essentially flat outer surfaces.

The solar fence providing improved ballistic protection 950′ can provide protection against small arms fire, blast, and fragmentation of explosive munition. Transparent sections, having no solar cells, can be included to allow observation while being partially obscured from enemy vision, and remaining protected. Firing portholes can also be included for the defenders. The thickness of the solar fence providing improved ballistic protection 950′ can be selected to provide the required strength and protection. Additional anti-blast plates or lamination can be added, for example on both sides, or on the vulnerable side only. The solar fence providing improved ballistic protection 950′ can be made of polycarbonate material that is strong and do not get shattered easily. The solar fence providing improved ballistic protection 950′ can be used in military installation, and places where vandalism is likely to occur. The solar fence providing improved ballistic protection 950′ can also be used as a rugged solar energy generation system, not as part of a fence.

Reference is now made to FIG. 9C schematically illustrating a 3-dimensional solar structure, in accordance with some exemplary embodiments of the disclosed subject matter.

The sun 812 is seen travelling from the east to the west in a trajectory 814. A 3-dimensional solar structure 910 having a zigzag profile is vertically positioned. The area on the ground is minimal, in comparison to the area that solar panels of the prior art occupy, since the surface of the panel 910 is directed upwardly. The current construction is vertical and therefore, occupies about approximately 5-10 percent of the surface of the prior art.

The zigzag profiled structure 910 can have one essentially flat front surface 911, and a patterned back surface 916 on which the solar cells attached. Alternatively, zigzag profiled structure 910 can be a relatively thin structure that comprises a first surface 916A that can be positioned faced to the west, as an example, and an opposite surface 916B that is substantially the same as the first surface, and positioned facing the east. Other directions are possible as well and depend on the positioning of the structure.

The thickness of the thin structure can be from about 2 mm thick to a few centimeters or more. In some cases, a sheet having thickness of about 2-5 mm is used. The width of the zigzag profile can be about 60 mm. The angle between successive surfaces is about 90 degrees and the distance between successive lows or highs is about 125 mm±5 mm. However, other parameters can be used.

The zigzag profiled structure 916 can be positioned as a fence that separates or bound areas in private, municipal, or national uses. Solar cells 918 are attached on a first surface 916A on the faces that are upwardly directed. Solar cells 920 are attached to the opposite surface 916B, on the surfaces that are upwardly directed. In this way, while the sun is in the east, the solar cells 920 on the opposite surface 916B are active in producing electricity while in the afternoon, when the sun travelled to the west, the solar cells 918 on the first surface 916A are active. In this way, although the structure 910 is vertically positioned and the area it occupies on the ground is minimal, the effectiveness of collecting the radiation coming from the travelling sun is maintained.

It should be mentioned that the 3D structure 910 is light relatively to the heavier constructions in the prior art, and can be as much as 50 percent lighter than the prior art structures. Therefore, its transportation is easy as well as its installation. Moreover, it can be placed in places where structures of reduced weight need to be used such as over water and on structures that are made of materials that are not strong but are cost effective.

It should be mentioned that optionally, not all the surfaces that are facing up must be covered with solar cells, and the spread of the solar cells is done according to the requirements of the system. In accordance with another embodiment, only one side is covered with solar cells and the other side is used in order to adhere the 3D structure to cover a wall or any other element that is vertical.

On surfaces facing the light, that are not covered by solar cells, mirrors can be glued (or the surface can be coated with reflective material), so as to increase the reflections of the light in the solar cells area and further increase their effectiveness during the day.

Reference is now made to FIGS. 9D and 9E schematically illustrating a 3-dimensional construction onto part of which or onto which solar cells are adhered, respectively, in accordance with some exemplary embodiments of the disclosed subject matter.

FIG. 9D illustrates a 3D structure 930 that can be used in the agriculture field as roofs of greenhouse, in animal farming, or in skylight, as examples.

Structure 932 can have a first surface 911 which is essentially flat, and the structure 930 is preferably install with the first surface 911 facing up or towards the sun. Alternatively, structure 932 is thin and corrugated. Structure 932 can be made of a material that is transparent such as glass, polycarbonate, a combination thereof, or the like.

Structure 932 can be colored or tinted to control the amount ad wavelength of the penetrated light.

The 3D structure 930 comprises a thin sheet, or a structure 932 of transparent material having an upper surface in zigzag profile, and optionally a flat lower surface. The upper surface of the thin sheet or structure 932 is partially covered with solar cells 934. The covered surfaces are the surfaces that are all facing to the same direction while the surface that faces the other directions are left uncovered. Since the thin sheet or structure 932 is transparent, light can penetrate to the other side of the 3D structure 930. Light beams penetrate the roof structure 930 as shown by arrows 936.

In accordance with other embodiments, the thin sheet or structure 932 can be transparent but pigmented so that the light passing through the transparent surfaces is colored. This can be used in certain croup that grow better through colored light.

In accordance with yet another preferred embodiment, the transparent portions that are not covered by solar cells can be provided with filters.

FIG. 9E illustrates a 3D structure 940, comprises a thin sheet 942 of a material that can be transparent or not transparent.

The whole upward facing surfaces of 3D structure 940, are covered with solar cells. Solar cells 944 directed to a certain direction, while solar cells 946 are facing to the opposite directions. Also in this case, in accordance with another embodiment, some of the surfaces can be covered with mirrors that reflects the light beams to the other opposing solar cells.

The 3D structure 940 can be used to cover warehouses, where light is not desired to penetrate the structure through the roof. The same structure can be used also to cover the walls of the building or the warehouse.

It should be mentioned that there is no limit to the length or width of the 3D structure.

It should be emphasized that the solar cells are adhered to the structure that will be used as roof or wall, rather than being embedded within a construction that is installed onto roofs. This is one of the reasons why the 3D structure is lighter than the conventional structures.

Another shortcoming associated with prior art constructions is that the panels are getting very hot and therefore, hot spots are formed on the solar cells that limits the effectiveness of the panels. Cooling the panels is required, which is sometimes performed by sprinklers. This increases the cost and complexity of the solar system. The present subject matter is a solar panel that is incorporated in the roof so the air-condition from the interior of the warehouse or building cools the solar cells. This also keeps the solar cells more effective over time.

Another advantage of the present subject matter relative to the conventional solar panels is that the whole roof can be covered with the solar cells since the direction of the panels is not limited to the south. Other directions are possible as well, so the possibilities are greater.

Reference is now made to FIG. 9F(i) schematically illustrating the light rays' trajectories within a solar prism, and the advantages of this prism, in accordance with some exemplary embodiments of the disclosed subject matter.

Transparent prism 990 can be one of prism in an array of similar or identical prisms. It is demonstrated here in a cross-section view, as a right-angle triangle, having: a side (front) surface 988, an upper (back) surface 987, and a lower (back) surface 989 on which the solar cells are attached. However, the size and angels of the prism can be selected to fit the needs, for example, taking into account the intended latitude where it will be used, the orientation of installation, shading of other structures, time of day when energy is most desired, total efficiency, etc.

When used in a solar-fence, which can be oriented according to the civil engineering needs, for example at a road-side, or a perimeter of a property, the sun rays can arrive from many directions, including opposing directions such as rays 991 and 994.

A conventional solar panel can perform poorly in these uses, as its opaque support blocks the light during at least part of the day.

In contrast, in the exemplary embodiment, light arriving from the right 991 can arrive directly to the solar cells after refracting on side surface 988, or by penetrating through the side surface 988 and being reflected off upper surface 987.

Similarly, light arriving from above 992 can arrive directly to the solar cells after refracting on upper surface 987, or by penetrating through the upper surface and being reflected off side surface 988.

Similarly, light arriving from the left 994 can arrive directly to the back side of the solar cells, or by penetrating through the upper surface 987 and being reflected off side surface 988.

Reference is now made to FIG. 9F(ii) schematically illustrating some light rays' trajectories in a vertical array of solar prisms, and the advantages of this prism, in accordance with some exemplary embodiments of the disclosed subject matter.

As to not clutter the drawings, only the paths of light arriving from the left 994 are seen in this figure.

Plate-like array 995 comprises a plurality of prisms 990. Prisms 990 can be attached to a transparent plate to form an array, or be manufactures such that necks 996 connects the prisms to form a plate. Side faces (also called front faces) are aligned to from a flat front surface 988, while the upper faces and lower faces form 3D structured back face.

Light arriving from the left 994 can arrive directly to the back side of the solar cells, or by penetrating through the upper surface 987 and being reflected off side surface 988. Further, light arriving from the left 994 can arrive to the back side of a solar cells in the adjacent prism by reflecting off the upper surface 987. As was mentioned before, dual-side solar cells can be used for efficiently harness light arriving at the back side of the solar cell. However, some available solar cell intended of one-sided illumination converts to electricity light arriving to their back side (at somewhat reduced efficiency), and these can be used.

As was noted throughout this document, the shape of the prisms can be adopted to the local conditions.

For example, in north Europe the sun only reaches 55 to 60 degrees over the horizon in mid-day, an angle of lower surface of the prism, where the solar cells are attached, of 50 to 60 degrees can be suitable for these locations.

For example, in central Europe the sun only reaches 65 to 70 degrees over the horizon in mid-day, an angle of lower surface of the prism, where the solar cells are attached, of 35 to 45 degrees can be suitable.

For example, in Israel the sun reaches 80 degrees over the horizon in mid-day, an angle of lower surface of the prism, where the solar cells are attached, of 30 to 40 degrees can be suitable.

For example, in China, where the sun can reach 85 degrees over the horizon in mid-day, an angle of lower surface of the prism, where the solar cells are attached, of 20 to 30 degrees can be suitable.

For example, in New York, where the sun can reach 72 degrees over the horizon in mid-day, an angle of lower surface of the prism, where the solar cells are attached, of 35 to 45 degrees can be suitable.

FIGS. 9G(i) to 9G(iii) schematically illustrate flexible array of prisms, in accordance with some exemplary embodiments of the disclosed subject matter.

Reference is now made to FIG. 9G(i) schematically illustrating a cross-sectional view of a flexible array of prisms, in its rolled state, in accordance with some exemplary embodiments of the disclosed subject matter.

Flexible array of prisms 970 comprises a plurality of rigid or semi-rigid prisms 972, each with a solar cell 973 attached to its lower surface. The plurality of prisms 972 are then attached to a flexible base sheet 971 that allows the flexible array of prisms 970 to be rolled for transportation or storage. Additionally, the flexibility of the flexible sheet 971 enable deploying it on curved surfaces (convex or concave). Flexible sheet 971 can be opaque, for example for deployment on a wall or a roof. Alternatively, flexible sheet 971 can be transparent for deployment on a transparent plate, to be deployed as a partially transparent skylight, partially transparent window, roof of agricultural green house, or a solar fence. In these applications, semi-transparent solar cells can be used, and/or partial coverage of the flexible sheet 971 by the solar cells.

Note that other type pf prisms, for example as seen in other figures throughout this document can be used.

Optionally, thin-film solar cells are used with the flexible array of prisms 970. Thin-film solar cells are typically of low efficiency, however the addition of prisms 972 increases the effective area of the solar cells and their efficiency up to two-folds. This can allow operating the flexible array of prisms 970 at low light levels, for example in room-light. The flexibility of the thin-film solar cells allows using small prisms 970, and rolling the entire flexible array of prisms 970 without having to align the solar cells to the prisms as needed when rigid or semi-rigid solar cells, which can bend only along pre-scribed grooves are used. This greatly reduces the cost and complexity of manufacturing.

Optionally a thin, semi-flexible film is embossed with prisms 972, a thin-film solar cells sheet is attached to it, and a protective coating or lamination is optionally applied to the thin-film solar cells sheet to form the flexible array of prisms 970. In this case the entire flexible array of prisms 970 can be 0.5 mm to few mm thick.

Reference is now made to FIG. 9G(ii) schematically illustrating a isometric view of a flexible array of prisms, deployed on a surface, in accordance with some exemplary embodiments of the disclosed subject matter.

In this example, the flexible array of prisms 970 is unrolled and attached to a surface 960. Surface 960 can be a rooftop or a wall. Attachment can be done using adhesive or fasteners (not seen herein). Lage flexible array of prisms 970 can be cut to size in between two adjacent prisms. Large areas can be covered by a plurality of flexible array of prisms.

Reference is now made to FIG. 9G(iii) schematically illustrating a cross-sectional view of a flexible array of prisms, deployed on a surface, showing some path of light rays, in accordance with some exemplary embodiments of the disclosed subject matter.

As the sun 812 travels along its daily and seasonally path 814, the flexible array 970 (seen herein deployed on a horizontal surface, but tilted or curved surface can be used), can take advantage of rays arriving from any directions such as demonstrated for example for rays 974, 975, 976 and 977. To reduce the cluttering of the figure, light reflected from one prism to the adjacent prism (similarly to FIG. 9F(ii) were omitted.

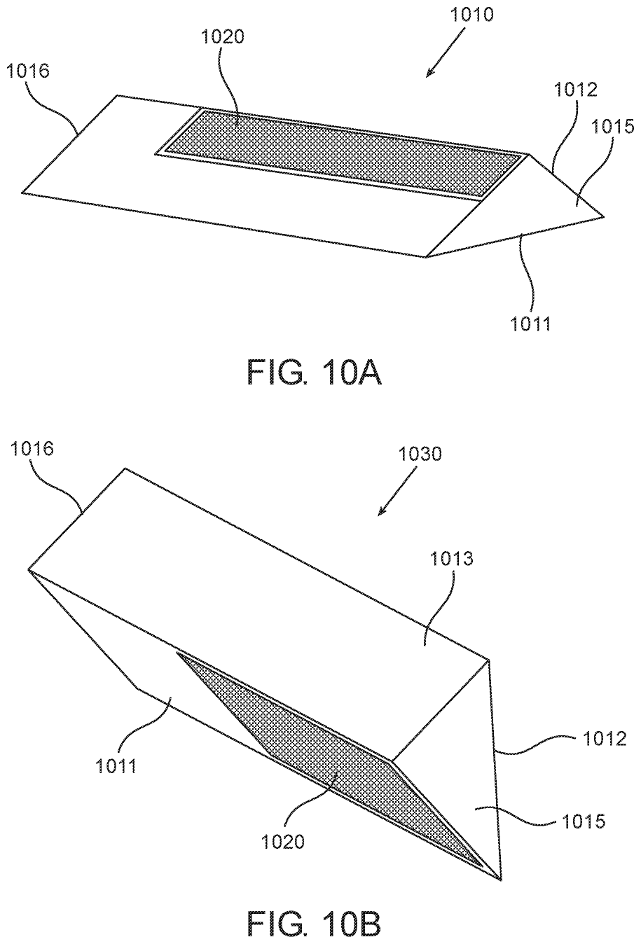

FIGS. 10A to 10B schematically illustrating semi-transparent prisms, in accordance with some exemplary embodiments of the disclosed subject matter. In some embodiment the prisms are hollow, and optionally are full of water.

Reference is now made to FIG. 10A schematically illustrating an isometric view of a semi-transparent prism, in accordance with some exemplary embodiments of the disclosed subject matter.

Semi-transparent prism 1010 is having a bottom (front) surface 1011, two side surfaces 1012 and 1013, and two ends 1015 and 1016.

In the depicted example, solar cell 1020 is attached to, and covers a portion of one of the side surfaces 1012 or 1013. This allows some of the light impinging on the semi-transparent prism 1010 to go through the semi-transparent prism. Thus, Semi-transparent prism 1010 can be used, alone or in an array, as partially transparent roof, skylight, or window.

Reference is now made to FIG. 10B schematically illustrating an isometric view of a semi-transparent prism, in accordance with some exemplary embodiments of the disclosed subject matter.

Semi-transparent prism 1030 is having a bottom (front) face 1011, two side (back) faces 1012 and 1013, and two ends 1015 and 1016.

In the depicted example, solar cell 1020 is attached to, and covers a portion of bottom surface 1011. This allows some of the light impinging on the semi-transparent prism 1030 to go through the semi-transparent prism. Thus, Semi-transparent prism 1010 can be used, alone or in an array, as partially transparent roof, skylight, or window.

It should be noted that the location, sizes and the portion of coverage of the solar cell 1020 seen herein are to be used as non-limiting examples, and other parameters can be used. Optionally, a plurality of solar cells can be used on the same prism, optionally on different surfaces. Alternatively, the solar cells can cover the entire surface.

One advantage of the rectangular solar cell seen in use with the elongated prisms is the ease of producing the solar cell patches 1020. Solar cells are usually procured as large sheets that are cut to size. The large solar sheets are often pre-grooved so they can easily be cut to rectangular shaped patches. In contrast. Cutting triangular, or other shapes having non-right-angles shaped patches can be difficult and can cause waste of solar cell material. Up to 50% loss of solar cell material can be caused when cutting octagonal patches.

Optionally, the elongated prisms are made as hollow shells, having their two ends 1015 and 1016 open. On deployment, the hollow shells are filled with water. Since the index of refraction of water is close to the index of refraction of plastic and glass, the water filled prism has similar optical properties of a solid prism. The prismatic shells can be produced by extrusion, they are lighter to transport, and are cheaper due to the low cost of water compared to glass or plastic.

Additionally, the hollow shells can be used to conduct a flow of water from one end to the other. The flow of water can be used for cooling the solar cells, thus increasing their efficiency.

Additionally, and optionally, the hollow shells with water circulation or flow, can be used as part of solar collator for solar hot water system, providing both electricity and hot water at the same time.

In High-rise buildings, the rooftop can be too small for installing solar heat collectors for all the apartments, and the hot water can get cold on its long way from the roof to the lower floors. In these cases, the water-filled solar prisms can be installed on the wall facing the sun of the high-rise building, providing hot water directly to the apartments, while providing electricity at the same time.

Alternatively, the hollow shells are left empty and optionally holes are drilled in at least one of their surfaces to allow air circulation or flow for colling the solar cells.

Cooling the solar cells in prismatic light concentrator can be more important than in traditional solar panels since due to the light concentration, higher temperatures can occur. Not only that high temperature decrees the efficiency of the solar cells, temperature variation can cause cracks in the solar cells. The Plastic (or glass) used to make the prisms has lower heat conduction properties, and thus can contribute to overheating.

In applications where only one side of the prisms is exposed to the sun, metallic plate, (for example aluminum), optionally having heat-sink fins exposed to the air, can be used for spreading and dissipating the heat.

Up to 18% efficiency and 50% light transmission can be achieved with these semi-transparent light concentrating prisms.

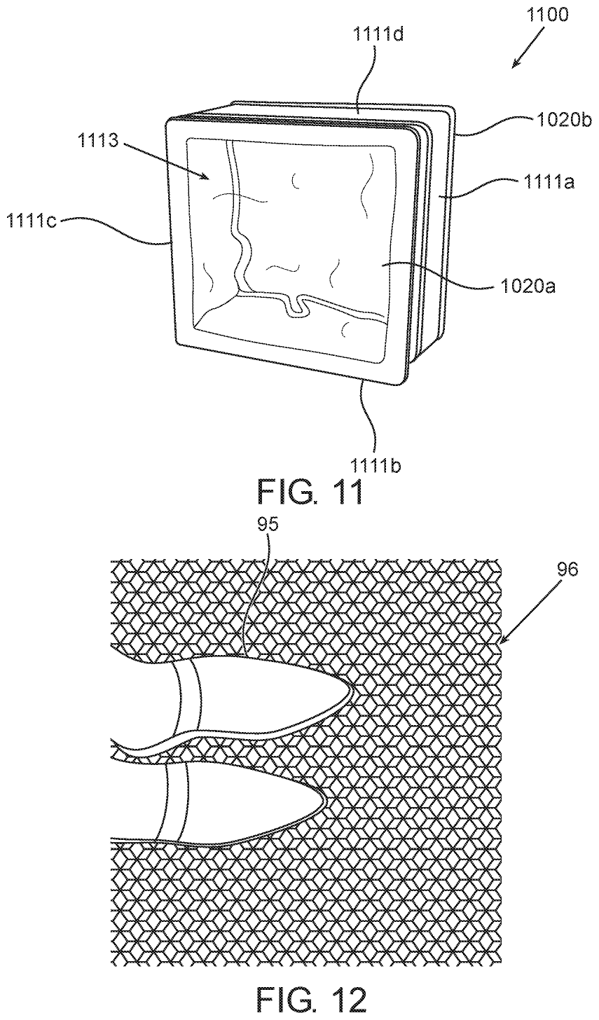

Reference is now made to FIG. 11 schematically illustrating an isometric view of a solar producing glass block, in accordance with some exemplary embodiments of the disclosed subject matter.

Glass blocks 1100 are used as building material. Each glass block 1100 has side surfaces 1111a, 111b, 111c, and 111d, and front and back surfaces 1120a and 1120b. The interior 1113 of block 1100 is empty to reduce weight and cost. By attaching at least one solar cell to at least one of the surfaces, block 1100 is capable of producing electricity. The solar cell (not seen in this figure) can be attached on the inside or on the outside of block 100.

Glass blocks 1100 can be used to erect walls, or be combined within architectural structure to provide light, strength, building bulk, esthetic value, and provide electricity at the same time.

Referring to FIG. 12 schematically illustrating solar 3D solar panel, used as pedestrian pavement or walkway 96, in accordance with an embodiment of the disclosed subject matter.

In the depicted, non-limited example, a plate-like 3D solar panel 96 can be of the type disclosed herein, having the prisms facing up, and covered with a flat transparent plate so that the shoes 95 of the pedestrian would not get excessive friction and ware.

Alternatively, a flat-top 3D plate-like panel disclosed herein, for example panel 951′ seen in FIG. 9B(ii) can be used. The 3D solar panel 96 can be places side by side to form a walkway.

Although the subject matter has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present subject matter.

1. A prismatic solar concentrator comprising:
a plurality of prisms made of transparent material, each of said prisms has a front face, and at least three back faces, wherein each of said prisms is attached to the adjacent prisms such that their front faces are aligned, forming a plate-like solar array having a flat front surface and 3-dimensional structured back surface; and
a plurality of solar cells producing electrical power in response to light, wherein the plurality of solar cells is attached to some of said back faces of said plurality of prisms.

2. The prismatic solar concentrator of claim 1, wherein each of the prisms is in a form of a solid corner cube having three back faces substantially at right angle to each other.

3. The prismatic solar concentrator of claim 2, wherein one solar cell is attached to one back face of each of the prisms, allowing light to pass through the plate-like solar array.

4. The prismatic solar concentrator of claim 2, wherein two solar cells are attached two back faces of each of said prisms, allowing light to pass through the plate-like solar array.

5. The prismatic solar concentrator of claim 2, wherein two solar cells are attached three back faces of each of the prisms.

6. The prismatic solar concentrator of claim 3, 4, or 5, wherein at least one solar cell only covers a portion of the back face it is attached to, allowing light to pass through the plate-like solar array.

7. The prismatic solar concentrator of claim 1, wherein each of the prisms is in a form of an elongated prism having a front face, two back faces, and two ends, wherein each of the prisms is attached to an adjacent prisms at their side faces, such that their front faces are aligned, forming a plate-like solar array having a flat front surface and 3-dimensional structured back surface, wherein the plurality of solar cells is producing electrical power in response to light are attached to at least some of said back faces of said plurality of prisms.

8. The prismatic solar concentrator of claim 7, wherein each of the prisms is a solid transparent prism.

9. The prismatic solar concentrator of claim 7, wherein each of the prisms is a shell of transparent prism, open in the two ends.

10. The prismatic solar concentrator of claim 9, wherein in operation, said shells of transparent prisms are filled with water.

11. The prismatic solar concentrator of claim 10, wherein in operation, the water is flowing through said shells, cooling said solar cells.

12. The prismatic solar concentrator of claim 11, wherein in operation, the water flowing through said shells, cooling said solar cells, heating the water, and providing hot water.

13. The prismatic solar concentrator of claim 9, wherein at least some of said shells have holes in them to allow air circulation through said shells to cool said solar cells.

14. The prismatic solar concentrator of claim 7, wherein the solar cells are rectangular.

15. The prismatic solar concentrator of claim 7, wherein at least some of said solar cells is covering only a portion of the back faces they are attached to.

16. The prismatic solar concentrator of claim 2 or 8, wherein when positioned vertically, the prismatic solar concentrator can be used as a wall or a part of a wall.

17. The prismatic solar concentrator of claim 2 or 8, wherein when positioned vertically, the prismatic solar concentrator can be used as a fence.

18. The prismatic solar concentrator of claim 17, wherein said fence is an acoustic fence.

19. The prismatic solar concentrator of claim 18, wherein the three-dimensional structure of the face of said acoustic fence has better sound absorbing properties than a flat surface acoustic fence.

20. The prismatic solar concentrator of claim 2 or 8, wherein when positioned horizontally, with its front face facing upwards, the prismatic solar concentrator can be used as a walkway.

21. The prismatic solar concentrator of claim 2 or 8, wherein said plurality of solar cells are thin-film solar cells.

22. The prismatic solar concentrator of claim 2 or 8, wherein said plurality of solar cells are dual-sided solar cells, intended to generate electricity in response to light received on any sided of said dual-sided solar cells.

23. The prismatic solar concentrator of claim 2 or 8, wherein the solar cells are single-sided solar cells, intended to generate electricity in response to light received on the active face of said single-sided solar cells, and wherein the active faces of said single-sided solar cells are facing the sun-facing side of the prismatic solar concentrator, and wherein at least a portion of the light arriving to the side opposing the sun-facing side of the prismatic solar concentrator is reflected or refracted to fall on said active faces of said single-sided solar cells.

24. A flexible solar array of prisms comprising:
a plurality of rigid or semi-rigid elongated prisms, each having a bottom face, arranged side-by-side such that all their bottom faces are facing the same direction;
a sheet of thin-film flexible solar cell attached at its first side to bottom faces of the elongated prisms, creating a flexible sheet-like solar array of prisms; and
a flexible base sheet attached to the second side of said sheet of thin-film flexible solar cell.

25. The flexible solar array of prisms of claim 24, wherein the flexible solar array of prisms can be rolled for transportation and storage, and can be unrolled to be deployed for solar energy generation.

26. The flexible solar array of prisms of claim 24, having efficiency of at least 50% larger than a corresponding area of a comparable thin-film solar cell.
